(19) United States
(12) Patent Application Publication
(10) Pub. No.: US 2012/0021555 A1
(43) Pub. Date: Jan. 26, 2012

(54) PHOTOVOLTAIC CELL TEXTURIZATION

(75) Inventors: Chih-Chiang Tu, Tauyen (TW); Chun-Lang Chen, Tainan County (TW)

(73) Assignee: TAIWAN SEMICONDUCTOR MANUFACTURING COMPANY, LTD., Hsin-Chu (TW)

(21) Appl. No.: 12/842,119

(22) Filed: Jul. 23, 2010

(51) Int. Cl. H01L 31/0236; H01L 31/18

(52) U.S. Cl. 438/71; 257/E31.13

(57) ABSTRACT

A photovoltaic cell texturization method is disclosed. The method includes providing a photovoltaic cell substrate; and texturizing a surface of the photovoltaic cell substrate. The texturizing implements a nanoimprint lithography process to expose a portion of the surface of the photovoltaic cell substrate. An etching process is performed on the exposed portion of the exposed portion of the surface of the photovoltaic cell substrate.

### TECHNICAL FIELD

The present disclosure relates generally to photovoltaic cells, and more particularly, to photovoltaic cell manufacturing.

### BACKGROUND

Texturization is used in manufacturing photovoltaic cells (also referred to as solar cells). In photovoltaic cells, texturization involves creating a textured surface of a substrate (or wafer). Texturization can increase reflection of light incident on its surface, thereby leading to greater absorption of the light inside the photovoltaic cell; reduce reflecting power or optical reflectivity of the surface, thereby reducing incident light loss; and increase the length of the optical path travelled by the incident light. In a photovoltaic cell, these characteristics lead to increased optical conversion efficiency, the effectiveness with which light is transformed into electricity.

Current texturization methods produce random, uncontrollable textured surfaces. This can lead to non-uniform light path lengths, thus leading to unpredictable reflection. One texturization method is wet etching. Though wet etching provides broad surface texturization, its random distribution prevents designable surface texturization. Wet etching is also easily affected by surface contamination or doping species, which has been observed to affect etching rates and uniformity, ultimately affecting the surface structure and roughness. Another texturization method is dry etching, for example, plasma etching (including random plasma etching and microdispersion plasma etching (such as a nanosphere lithography process)). Though plasma etching can provide more uniform surface texturization (including better antireflection properties and controllable aspect ratios), a photolithography process is required, causing increased manufacturing costs and lower throughput. For example, nanosphere lithography includes forming a nanosphere material over the substrate, performing photolithography and a first etch to shape the nanosphere material into a desired shape and dimension, and performing a second etch to transfer the pattern of the etched nanosphere material to the substrate. The pattern of the substrate is thus dependent on the nanosphere distribution achieved by the photolithography and first etch. It has been observed that nanosphere lithography processes suffer from random patterning and distribution control issues. Yet another texturization method includes laser and/or mechanical scribing/machining. Though these methods produce more uniform and controllable surface patterns, these methods have been observed to induce substrate damage and/or lattice defects in the substrate. This can lead to electron-hole pair recombination and reduced optical conversion efficiency. Accordingly, although existing texturization methods have been generally adequate for their intended purposes, they have not been entirely satisfactory in all respects.

### SUMMARY

The present disclosure provides for many different embodiments. According to one of the broader forms of an embodiment of the present invention, a method includes: providing a photovoltaic cell substrate; and texturizing a surface of the photovoltaic cell substrate. Texturizing the surface includes performing a nanoimprint lithography process to expose a portion of the surface of the photovoltaic cell substrate, and performing an etching process on the exposed portion of the surface of the photovoltaic cell substrate.

In another one of the broader forms of an embodiment of the present invention, a method includes: providing a photovoltaic cell substrate; forming a resist layer over the photovoltaic cell substrate; pressing a mold having a designable pattern feature into the resist layer to form a patterned resist layer, the patterned resist layer having a thickness contrast; removing the mold from the patterned resist layer; and etching the photovoltaic cell substrate using the patterned resist layer as a mask to form a textured surface in the photovoltaic cell substrate.

Yet another one of the broader forms of an embodiment of the present invention involves a method. The method includes: providing a solar cell substrate; forming a shielding layer over the solar cell substrate; providing a mold having a predetermined pattern feature; imprinting the shielding layer with the predetermined pattern feature of the mold; transferring the predetermined pattern feature from the shielding layer to the substrate to form a plurality of trenches in the solar cell substrate; and thereafter, removing the shielding layer from the solar cell substrate.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of an embodiment of a method for fabricating a photovoltaic device according to various aspects of the present disclosure.

FIGS. 2-7 are diagrammatic sectional side views of an embodiment of a photovoltaic device at various stages of fabrication according to the method of FIG. 1.

FIGS. 8-13 are diagrammatic sectional side views of another embodiment of a photovoltaic device at various stages of fabrication according to the method of FIG. 1.

FIGS. 14A-14D are perspective views of various embodiments of the photovoltaic device of FIG. 13.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

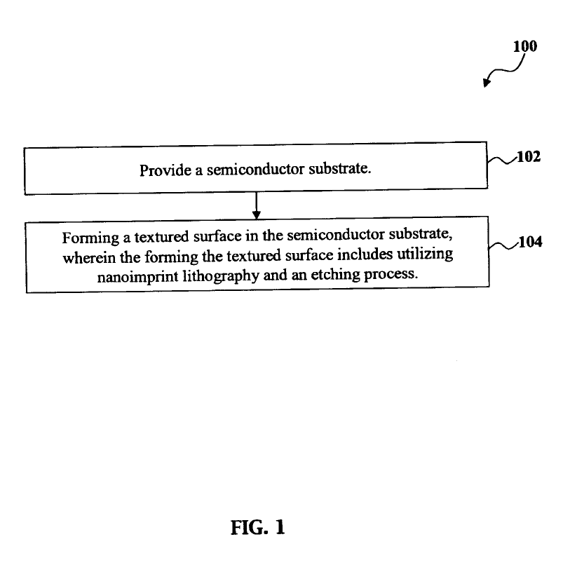

FIG. 1 is a flow chart of an embodiment of a method 100 for fabricating a photovoltaic device. As will be discussed further below, the method 100 is utilized to provide a textured surface for a photovoltaic device and to provide a photovoltaic device having an optical grating structure. The method 100 begins at block 102 where a semiconductor substrate is provided. At block 104, a textured surface is formed in the semiconductor substrate utilizing nanoimprint lithography and an etching process. The nanoimprint lithography utilizes thermal nanoimprinting lithography techniques (including thermoplastic and thermal-curable nanoimprinting), direct imprinting techniques (also referred to as embossing), UV nanoimprinting lithography (UV-NIL) techniques (also referred to as UV-curable nanoimprinting), or combinations thereof. Alternatively, the nanoimprint lithography utilizes other nanoimprinting lithography (NIL) techniques as known in the art, including future-developed NIL lithography techniques, and combinations thereof. The NIL process is performed in a vacuum environment, an air environment, or other suitable environment. The NIL process further utilizes various alignment techniques. The etching process is a dry etching process, wet etching process, other suitable etching process, or combination thereof. Additional steps can be provided before, during, and after the method 100, and some of the steps described can be replaced or eliminated for other embodiments of the method 100. The discussion that follows illustrates various embodiments of a photovoltaic device that can be fabricated according to the method 100 of FIG. 1.

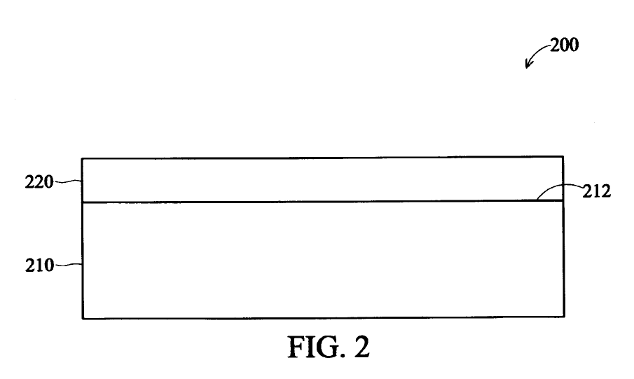

FIGS. 2-7 are diagrammatic sectional side views of an embodiment of a photovoltaic device 200 (also referred to as a solar cell), in portion or entirety, at various stages of fabrication according to the method of FIG. 1. FIGS. 2-7 have been simplified for the sake of clarity to better understand the inventive concepts of the present disclosure. Additional features can be added in the photovoltaic device 200, and some of the features described below can be replaced or eliminated for other embodiments of the photovoltaic device 200.

In FIG. 2, a substrate 210 is provided. The substrate 210 is a semiconductor substrate comprising silicon. The silicon comprises a single crystalline, multi-crystalline, polycrystalline, or amorphous silicon. The substrate 210 comprises any suitable crystallographic orientation (e.g., a (100), (110), or (111) crystallographic orientation). In the depicted embodiment, the semiconductor substrate 210 is a p-doped substrate. Alternatively, the semiconductor substrate 210 may be an n-doped substrate. Alternatively or additionally, the substrate 210 comprises another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

Referring to FIGS. 2-7, nanoimprint technology and an etching process is implemented to texture a surface 212 of the substrate 210, thereby forming a textured surface 212A in the substrate 210. In FIG. 2, a material layer 220 (also referred to as an intermedium or shielding layer) is formed over the substrate 210 (specifically over the surface 212 of the substrate 210) by a spin coating, flat scrubbing, or other suitable process. A cleaning process, such as an RCA clean, may be performed prior to forming the material layer 220, to remove contaminants from the surface 212 of the substrate 210. The material layer 220 is a resist layer. The resist layer is a homopolymer resist, such as PMMA (polymethylmethacrylate) or PS (polystyrene), thermal plastic resist; UV-curable resist; resist material including siloxane copolymers, such as PDMS (poly(dimethyl siloxane))-organic block or graft copolymers; thermally curable liquid resist; UV-curable liquid resist for room temperature nanoimprinting; other suitable resist material as known in the art; future-developed resist material; or combinations thereof. The material layer 220 may comprise a multi-layer structure. The material layer 220 is a suitable thickness, for example, from about a few hundred angstroms (Å) to about several micrometers (μm). In the depicted embodiment, the material layer 220 has a thickness from about 1,000 Å to about 1 μm.

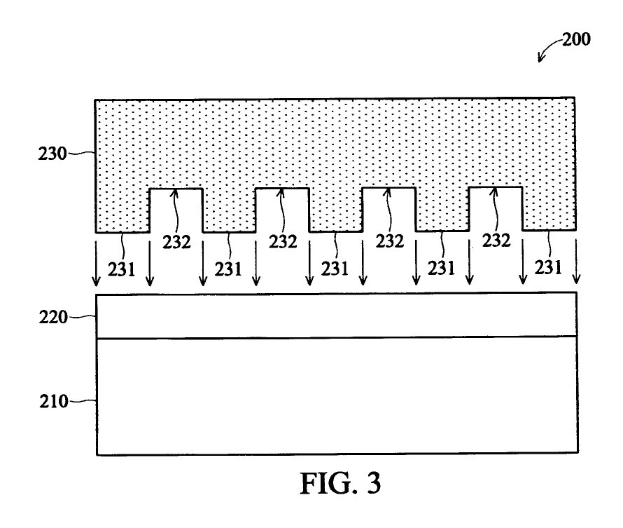

Referring to FIGS. 3-5, a mold 230 is pressed into the material layer 220 and removed, thereby imprinting the material layer 220 with a predetermined pattern. The mold 230 includes protrusion features 231 and openings 232 (also referred to as cavities) that form the predetermined pattern. The predetermined pattern is designable, and thus, the protrusion features 231 and openings 232 may comprise various shapes and designs depending on the particular pattern or feature desired. In the depicted embodiment, the mold 230 comprises silicon. Alternatively, the mold 230 comprises quartz (SiO₂), SiC, silicon nitride, metal, sapphire, diamond, resin, other suitable mold material as known in the art, future-developed mold material, or combinations thereof. In an example, the mold 230 may comprise quartz having a patterned metal layer, such as chromium (Cr), forming the predetermined pattern. In another example, the mold 230 may comprise quartz having a patterned MoSi layer forming the predetermined pattern.

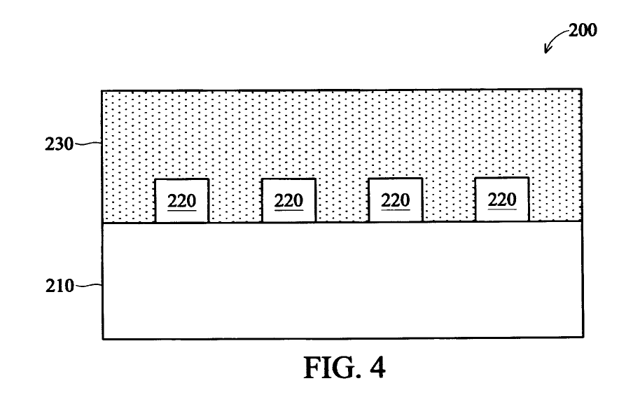

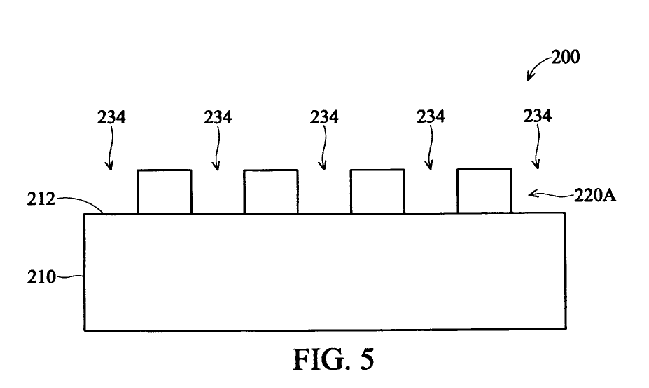

As noted above, the mold 230 is pressed into the material layer 220 (FIGS. 3 and 4) at a suitable temperature and pressure, thereby creating a thickness contrast in the material layer 220. More specifically, the predetermined pattern of the mold 230 is transferred to the material layer 220 because the material layer 220 underneath the protrusion features 231 is displaced and transported to the cavities 232 of the mold 230 (FIG. 5). The temperature and pressure is selected based on properties of the mold 230 and material layer 220, and the imprinting is performed in a vacuum or in air. The material layer 220 is cured and set so that the material layer 220 hardens and assumes its displaced shape. This ensures that, when the mold 230 is removed, the material layer 220 will not flow back into spaces created by the displacement of the material layer 220. For example, where the material layer 220 is a thermal resist, the temperature may be raised higher than the material layer's glass transition temperature so that the material layer 220 changes to a liquid state, such that it is displaced and transported into the cavities 232 of the mold 230. Once the material layer 220 conforms to the pattern of the mold 230, the temperature may be brought below the material layer's glass transition temperature to solidify the material layer 220. In another example, where the material layer 220 is a thermal or UV curable material, the material layer 220 may initially be in a liquid state, such that it conforms to the mold 230 when pressed into the material layer 220, and then, solidifies when cured by a thermal curing, UV curing, or combination thereof. Other curing and setting processes may be used.

When the mold 230 is removed, a patterned material layer 220A remains as illustrated in FIG. 5. In the depicted embodiment, the patterned material layer 220A includes openings 234 that expose portions of the substrate 210, particularly portions of the surface 212 of the substrate 210. The patterned material layer 220A shields the other portions of the substrate 212 from subsequent processing (such as an etching process). A thin residual layer of the material layer 220 may remain over the exposed portions of the substrate 210.

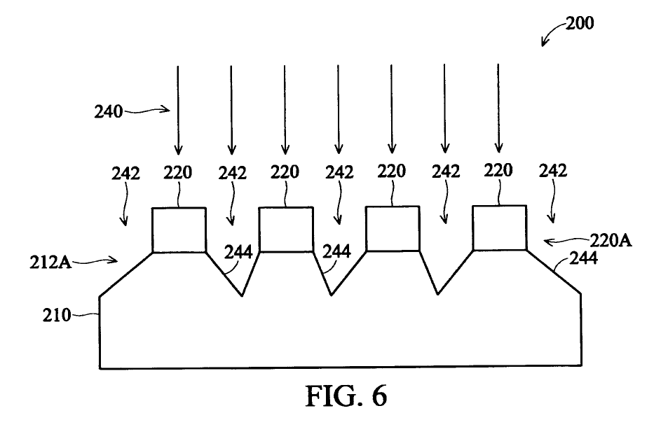

In FIG. 6, an etching process 240 is performed on the substrate 210. Particularly, the etching process 240 is applied to the exposed portions of the substrate 210, portions of the surface 212. In the depicted embodiment, the etching process 240 is a wet etching process. The wet etching process utilizes a basic solution or an acid solution. An exemplary basic etching solution includes KOH (potassium hydroxide), IPA (isopropyl alcohol), or combination thereof. An exemplary acid etching solution includes HNO₃ (nitric acid), HF (hydrofluoric acid), or combination thereof. Alternatively, the basic or acid etching solutions include other etching solutions as known in the art, including future-developed basic or acid etching solutions. Further, in an alternate embodiment, a combined dry and wet etching process may be implemented. In situations where a residual layer of the material layer 220 remains over the exposed portions of the substrate 210, the etching process 240 may also remove the residual layer, or a dry etching process, such as a reactive ion etching (RIE) process, may be utilized to remove the residual layer prior to performing the etching process 240.

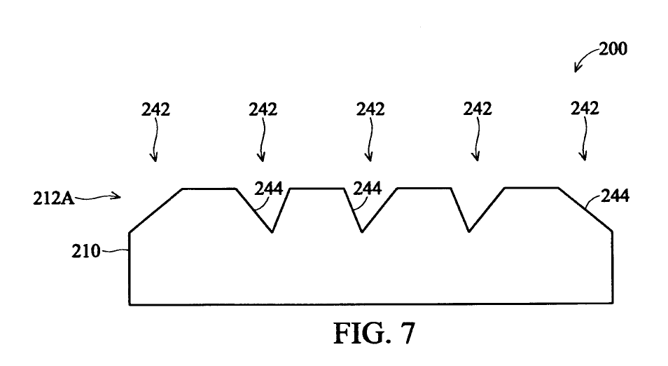

The etching process 240 transfers the pattern (or design) of the patterned material layer 220A to the substrate 210 (which as noted above reflects the predetermined designable pattern of the mold 230). More specifically, the etching process 240 forms openings 242 in the surface 212 of the substrate, thereby forming the textured surface 212A. The textured surface 212A thus includes openings 242 that are defined by tapered surfaces 244. In the depicted embodiment, the openings 242 are defined by at least two tapered surfaces 244 to form v-shaped openings. Alternatively, other shaped openings are contemplated. Further, each of the openings 242 may include the same shape or various shapes. The patterned material layer 220A is subsequently removed by a suitable process, such as a stripping process, as illustrated in FIG. 7. In the depicted embodiment, the pattered material layer 220A is removed by a solution including sulfuric acid (H₂SO₄) and hydrogen peroxide (H₂O₂). Alternatively, other solutions as known in the art, including future-developed solutions, are used for removing the patterned material layer 220A.

The textured surface 212A of the photovoltaic device 200 thus has multiple trenches 242 and tapered surfaces 244. The nanoimprint lithography and etching process described above achieves the textured surface 212A, which has a more complex, highly concentrated structure as compared to conventional photovoltaic devices. The complex, highly concentrated textured surface 212A facilitates increased trapping of light within the textured surface 212A. By increasing the trapping of light incident on the textured surface 212A, the optical path length is elongated and the likelihood of light being absorbed by the photovoltaic device 200 is increased. Also, increasing the light path length generates an increased number of electron-hole pairs. Thus, the longer optical path lengths and increased light trapping achieved by the textured surface 212A provides the photovoltaic device 200 with increased energy conversion efficiency and increased light-trapping effects. Further, using nanoimprint lithography provides precise control over the pattern of the textured surface 212A, for example, in contrast to nanosphere lithography. More specifically, the distribution and dimensions of the pattern can be easily controlled by the predetermined pattern of the mold 230. And, compared to other texturization processes (such as photolithography and/or nanosphere lithography), the complex, highly concentrated structure is more easily achieved using the mold 230 having the predetermined pattern, which can be designed to achieve a pattern that is ideal for the optimum adsorption wavelength of the photovoltaic device 200.

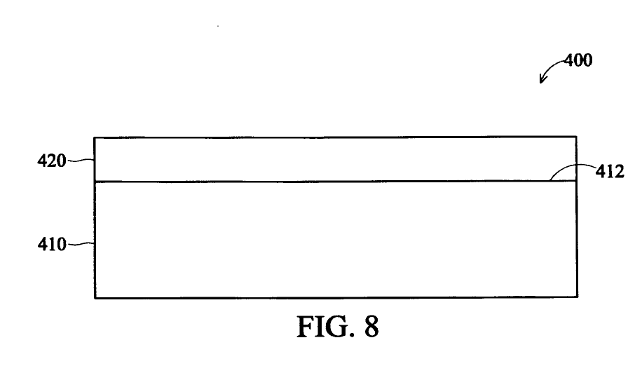

FIGS. 8-13 are diagrammatic sectional side views of another embodiment of a photovoltaic device 400 (also referred to as a solar cell), in portion or entirety, at various stages of fabrication according to the method of FIG. 1. FIGS. 8-13 have been simplified for the sake of clarity to better understand the inventive concepts of the present disclosure. Additional features can be added in the photovoltaic device 400, and some of the features described below can be replaced or eliminated for other embodiments of the photovoltaic device 400.

In FIG. 8, a substrate 410 is provided. The substrate 410 is a semiconductor substrate comprising silicon. The silicon comprises a single crystalline, multi-crystalline, polycrystalline, or amorphous silicon. The substrate 410 comprises any suitable crystallographic orientation (e.g., a (100), (110), or (111) crystallographic orientation). In the depicted embodiment, the semiconductor substrate 410 is a p-doped substrate. Alternatively, the semiconductor substrate 410 may be an n-doped substrate. Alternatively or additionally, the substrate 410 comprises another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

Referring to FIGS. 8-13, nanoimprint technology and an etching process is implemented to texture a surface 412 of the substrate 410, thereby forming a textured surface 412A in the substrate 410. In FIG. 8, a material layer 420 (also referred to as an intermedium or shielding layer) is formed over the substrate 410 (specifically over the surface 412 of the substrate 410) by a spin coating, flat scrubbing, or other suitable process. A cleaning process, such as an RCA clean, may be performed prior to forming the material layer 420, to remove contaminants from the surface 412 of the substrate 410. The material layer 420 is a resist layer. The resist layer is a homopolymer resist, such as PMMA (polymethylmethacrylate) and PS (polystyrene); thermal plastic resist; UV-curable resist; resist material including siloxane copolymers, such as PDMS (poly(dimethyl siloxane))-organic block or graft copolymers; thermally curable liquid resist; UV-curable liquid resist for room temperature nanoimprinting; other suitable resist material as known in the art; future-developed resist material; or combinations thereof. The material layer 420 may comprise a multi-layer structure. The material layer 420 is a suitable thickness, for example, from about a few hundred angstroms (Å) to about several micrometers (μm). In the depicted embodiment, the material layer 420 has a thickness from about 1,000 Å to about 1 μm.

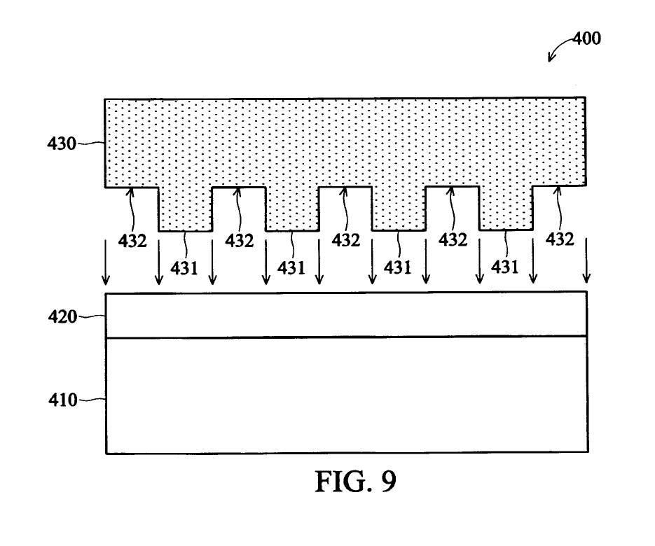

Referring to FIGS. 9-11, a mold 430 is pressed into the material layer 420 and removed, thereby imprinting the material layer 420 with a predetermined pattern. The mold 430 includes protrusion features 431 and openings 432 (also referred to as cavities) that form the predetermined pattern. The predetermined pattern is designable, and thus, the protrusion features 431 and openings 432 may comprise various shapes and designs depending on the particular pattern or feature desired. In the depicted embodiment, the protrusion features 431 and openings 432 are designed to form an optical grating structure having a desired pitch. The mold 430 comprises silicon, quartz (SiO₂), SiC, silicon nitride, metal, sapphire, diamond, resin, other suitable mold material as known in the art, future-developed mold material, or combinations thereof. In an example, the mold 430 may comprise quartz having a patterned metal layer, such as chromium (Cr), forming the predetermined pattern. In another example, the mold 230 may comprise quartz having a patterned MoSi layer forming the predetermined pattern.

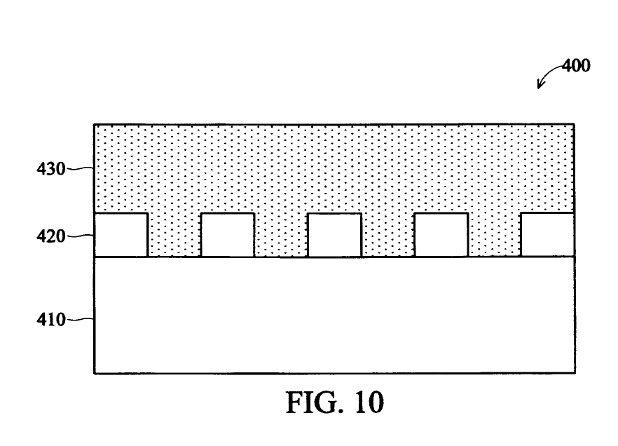

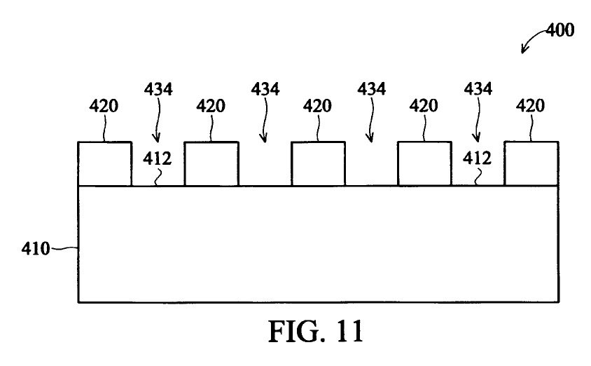

As noted above, the mold 430 is pressed into the material layer 420 (FIGS. 9 and 10) at a suitable temperature and pressure, thereby creating a thickness contrast in the material layer 420. More specifically, the predetermined pattern of the mold 430 is transferred to the material layer 420 because the material layer 420 underneath the protrusion features 431 is displaced and transported to the cavities 432 of the mold 430 (FIG. 11). The temperature and pressure is selected based on properties of the mold 430 and material layer 420, and the imprinting is performed in a vacuum or in air. The material layer 420 is cured and set so that the material layer 420 hardens and assumes its displaced shape. This ensures that, when the mold 430 is removed, the material layer 420 will not flow back into spaces created by the displacement of the material layer 420. For example, where the material layer 420 is a thermal resist, the temperature may be raised higher than the material layer's glass transition temperature so that the material layer 420 changes to a liquid state, such that it is displaced and transported into the cavities 432 of the mold 430. Once the material layer 420 conforms to the pattern of the mold 430, the temperature may be brought below the material layer's glass transition temperature to solidify the material layer 420. In another example, where the material layer 420 is a thermal or UV curable material, the material layer 420 may initially be in a liquid state, such that it conforms to the mold 430 when pressed into the material layer 420, and then, solidifies when cured by a thermal curing, UV curing, or combination thereof. Other curing and setting processes may be used.

When the mold 430 is removed, a patterned material layer 420A remains as illustrated in FIG. 11. In the depicted embodiment, the patterned material layer 420A includes openings 434 that expose portions of the substrate 410, particularly portions of the surface 412 of the substrate 410. The patterned material layer 420A shields the other portions of the substrate 212 from subsequent processing (such as an etching process). A thin residual layer of the material layer 420 may remain over the exposed portions of the substrate 410.

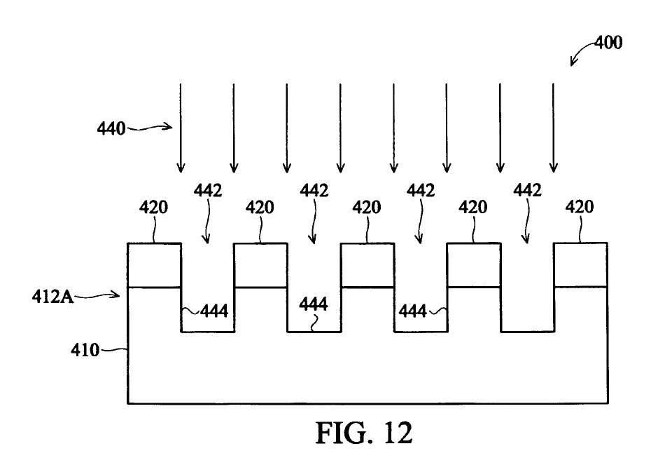

In FIG. 12, an etching process 440 is performed on the substrate 410. Particularly, the etching process 440 is applied to the exposed portions of the substrate 410, portions of the surface 412. In the depicted embodiment, the etching process 440 is a dry etching process. The dry etching process provides anisotropic etching, such that an etching profile in the substrate 410 can be controlled. An exemplary dry etching process is a plasma etching process that utilizes SF₆, CF₄, Cl₂, or combination thereof. Alternatively, the other dry etching processes as known in the art are utilized, including future-developed dry etching processes. Further, in an alternate embodiment, a combined dry and wet etching process may be implemented. In situations where a residual layer of the material layer 420 remains over the exposed portions of the substrate 410, the etching process 440 may also remove the residual layer, or a dry etching process, such as a reactive ion etching (RIE) process, may be utilized to remove the residual layer prior to performing the etching process 440.

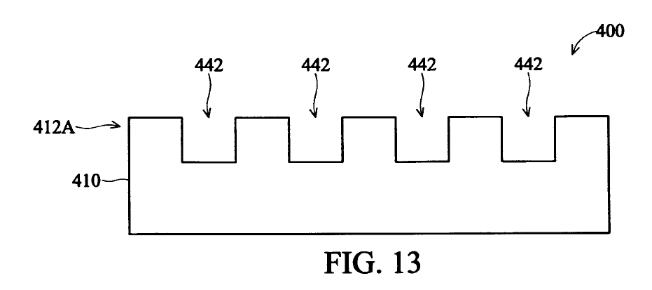

The etching process 440 transfers the pattern (or design) of the patterned material layer 420A to the substrate 410 (which as noted above reflects the predetermined designable pattern of the mold 430). More specifically, the etching process 440 forms openings 442 and posts 433 in the surface 412 of the substrate, thereby forming the textured surface 412A. The openings 442 may alternatively be referred to as gaps in some embodiments. In the depicted embodiment, the openings 442 are defined between posts 443. Alternatively, other shaped openings 442 and/or posts 443 are formed in the textured surface 412A. Further, each of the openings 442 and/or posts 443 may include the same shape or various shapes. The patterned material layer 420A is subsequently removed by a suitable process, such as a stripping process, as illustrated in FIG. 13. In the depicted embodiment, the pattered material layer 420A is removed by a solution including sulfuric acid (H₂SO₄) and hydrogen peroxide (H₂O₂). Alternatively, other solutions as known in the art, including future-developed solutions, are used for removing the patterned material layer 420A.

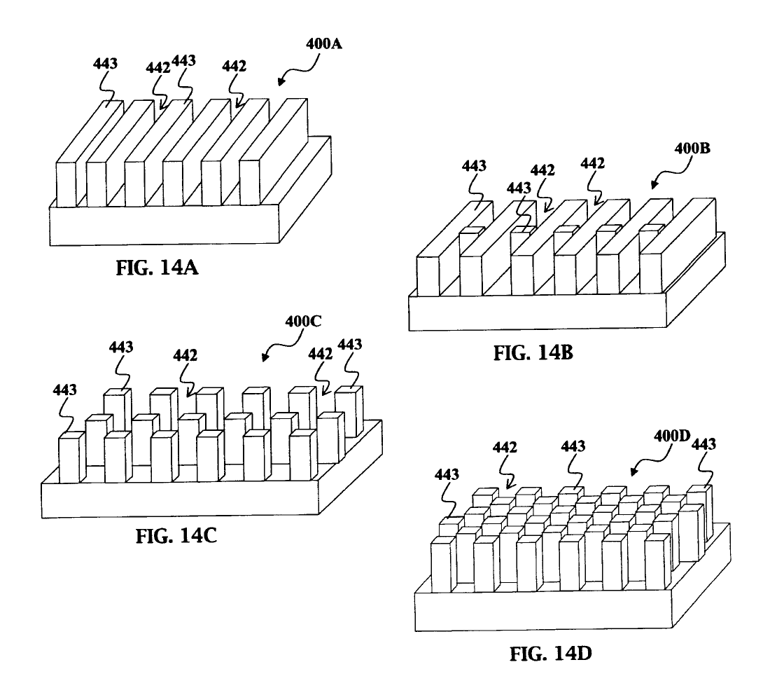

FIGS. 14A-14D are perspective views of various embodiments of the photovoltaic device 400 of FIG. 13. In the depicted embodiment, shown in FIG. 13, the openings 442 in the surface of the substrate 410 provide a textured surface 412A having a periodic structure, such as an optical grating structure. The periodic structure can have various designs. For example, the photovoltaic device 400 can exhibit periodic structures illustrated in FIGS. 14A-14D, such as periodic structure 400A, periodic structure 400B, periodic structure 400C, periodic structure 400D, variations thereof, or combinations thereof. The periodic structures 400A, 400B, 400C, 400D include gaps/openings 442 and ridges/posts 443. Periodic structure 400A includes periodically, alternating gaps/openings 442 and ridges 443. Periodic structure 400B includes ridges/posts 443 having different dimensions that alternate with various gaps/openings 442 disposed therebetween. Periodic structure 400C includes periodically, alternating gaps/openings 442 and ridges/posts 443 having different dimensions than the gaps/openings 442 and ridges/posts 443 of periodic structure 400A. Periodic structure 400D includes periodically, alternating gaps/openings 442 and ridges/posts 443, where each row of ridges/posts 443 is offset from an adjacent row of ridges/posts 443 by a width of the ridges/posts 443.

Pitch and pattern dimension of the periodic structure are selected based on an optimum adsorption wavelength of the photovoltaic device 400. The designable pattern feature of the mold is thus selected to achieve the desired pitch and pattern dimension of the periodic structure. In the depicted embodiments, the pitch is about 0.4 μm to about 0.8 mm, and a duty ratio is 1:1. For thin film solar cells, the pitch is about 0.2 μm to about 1 μm. The periodic structure of the photovoltaic device exhibits increased light trapping effects. The increased light trapping effect provides elongated light path length, which increases the number of electron-hole pairs generated within the photovoltaic device. Compared to conventional photovoltaic devices, the textured surface of the photovoltaic device, achieved by the disclosed nanoimprinting lithography and dry etching process, provides the photovoltaic device 400 with increased energy conversion efficiency and increased light-trapping effects. Further, as noted above, using nanoimprint lithography provides precise control over the pattern of the textured surface 412A, because the distribution and dimensions of the pattern can be easily controlled by the predetermined pattern of the mold 430.

The foregoing description discloses a photovoltaic cell texturization process that allows designable photovoltaic cell surface texturization. By implementing nanoimprinting lithography into the texturization process, it has been observed that the textured surfaces of photovoltaic surfaces are improved, leading to increased optical conversion efficiency. For example, the designable surface texturization provides textured surfaces with enhanced light trapping effects and longer light path lengths. The designable surface texturization also provides a way to achieve an optical grating structure for a photovoltaic cell. The disclosed photovoltaic cell texturization process also provides high throughput at low costs. For example, implementing nanoimprinting lithography into the texturization process eliminates the need for a photolithography process, which is often expensive and time consuming. Thus, nanoimprinting lithography provides a way to achieve photolithography characteristics without having to use a photolithography process in photovoltaic cell fabrication. It is understood that different embodiments may have different advantages, and that no particular advantage is necessarily required of any one embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
providing a photovoltaic cell substrate; and
texturizing a surface of the photovoltaic cell substrate, wherein the texturizing includes:
performing a nanoimprint lithography process to expose a portion of the surface of the photovoltaic cell substrate, and
performing an etching process on the exposed portion of the surface of the photovoltaic cell substrate.

2. The method of claim 1 wherein the performing the nanoimprint lithography process comprises:
forming a resist layer over the photovoltaic cell substrate;
providing a mold having a predetermined pattern; and
transferring the predetermined pattern to the resist layer, thereby forming an opening in the resist layer that exposes the portion of the photovoltaic cell substrate.

3. The method of claim 2 further comprising removing the resist layer after performing the etching process.

4. The method of claim 1 wherein the performing the etching process comprises transferring a predetermined pattern to the exposed portion of the surface of the photovoltaic cell substrate.

5. The method of claim 1 wherein the performing the etching process comprises performing a wet etching process.

6. The method of claim 1 wherein the performing the etching process on the exposed photovoltaic cell substrate comprises performing a dry etching process.

7. The method of claim 6 wherein the performing the dry etching process comprises performing a plasma etching process.

8. The method of claim 1 wherein the texturizing the surface of the photovoltaic cell substrate comprises performing the nanoimprint lithography and etching processes without performing a photolithography process.

9. A method for photovoltaic cell texturization, the method comprising:
providing a photovoltaic cell substrate;
forming a resist layer over the photovoltaic cell substrate;
pressing a mold having a designable pattern feature into the resist layer to form a patterned resist layer, the patterned resist layer having a thickness contrast;
removing the mold from the patterned resist layer; and
etching the photovoltaic cell substrate using the patterned resist layer as a mask to form a textured surface in the photovoltaic cell substrate.

10. The method of claim 9 further comprising removing remaining portions of the patterned resist layer after the etching.

11. The method of claim 9 wherein the designable pattern feature comprises a grating feature.

12. The method of claim 11 wherein the textured surface in the photovoltaic cell substrate comprises an optical grating structure.

13. The method of claim 9 wherein the designable pattern feature comprises a periodic structure.

14. The method of claim 13 wherein the periodic structure is a periodic post structure, a periodic gap structure, or a periodic post and gap structure.

15. The method of claim 13 wherein the periodic structure is a periodic post structure including a first row of posts adjacent to a second row of posts, wherein the first row of posts are offset from the second row of posts.

16. The method of claim 13 wherein the periodic structure has a duty ratio of about 1:1 and a pitch of about 0.4 μm to about 0.8 μm.

17. The method of claim 9 wherein the etching the photovoltaic cell substrate comprises performing a wet etching with a potassium hydroxide solution, isopropyl alcohol solution, a nitric acid solution, a hydrofluoric acid solution, or a combination thereof.

18. The method of claim 9 wherein the etching the photovoltaic cell substrate comprises performing a dry etching with a SF₆ plasma, CF₄ plasma, Cl₂ plasma, or a combination thereof.

19. A method comprising:
providing a solar cell substrate;
forming a shielding layer over the solar cell substrate;
providing a mold having a predetermined pattern feature;
imprinting the shielding layer with the predetermined pattern feature of the mold;
transferring the predetermined pattern feature from the shielding layer to the substrate to form a plurality of trenches in the solar cell substrate; and
thereafter, removing the shielding layer from the solar cell substrate.

20. The method of claim 19 wherein the predetermined pattern feature comprises a predetermined distribution of a plurality of cavities.
